(19) United States
(12) Patent Application Publication
(10) Pub. No.: US 2025/0253176 A1
(43) Pub. Date: Aug. 7, 2025

(54) POSITION DETECTION SYSTEM AND OPERATING METHOD THEREOF

(71) Applicants: TAIWAN SEMICONDUCTOR MANUFACTURING COMPANY, LTD., Hsinchu (TW); TSMC CHINA COMPANY LIMITED, Shanghai (CN)

(72) Inventors: Honghua ZHU, Shanghai City (CN); Jilong GU, Shanghai City (CN); Guo Ping HE, Shanghai City (CN)

(73) Assignees: TAIWAN SEMICONDUCTOR MANUFACTURING COMPANY, LTD., Hsinchu (TW); TSMC CHINA COMPANY LIMITED, Shanghai (CN)

(21) Appl. No.: 18/582,100

(22) Filed: Feb. 20, 2024

(30) Foreign Application Priority Data
Feb. 1, 2024 (CN) 202420258970.0

(51) Int. Cl. H01L 21/67; H01L 21/02; H01L 21/66

(52) U.S. Cl. CPC H01L 21/67259; H01L 21/02068; H01L 22/26

(57) ABSTRACT

A method includes placing a semiconductor substrate in a developing chamber; rotating a rinse arm, with a rinse nozzle, in the developing chamber based on a vertical axis; detecting a positioning status of the rinse arm through a position detection system; determining whether the positioning status of the rinse arm is acceptable through the position detection system; in response to the determination determines that the positioning status of the rinse arm is acceptable, performing a rinse process on the semiconductor substrate through the rinse nozzle installed on the rinse arm.

### PRIORITY CLAIM AND CROSS-REFERENCE

The present application claims priority to China Application Serial Number 202420258970.0, filed on Feb. 1, 2024, which is herein incorporated by reference.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart illustrating a method for semiconductor manufacturing in accordance with some embodiments of the present disclosure.

FIGS. 2A-2H illustrate cross-sectional views of a wafer at various stages of fabrication in accordance with some embodiments of the present disclosure.

FIG. 3 illustrates a schematic top view of a developing apparatus with a developing chamber and rinsing chamber in accordance with some embodiments of the present disclosure.

FIGS. 4A and 4B illustrate schematic views of a developing chamber in a developing apparatus in accordance with some embodiments of the present disclosure.

FIGS. 5A, 6A, 7A, and 8A illustrate schematic views of various stages of a method for operating a positioning module with a position detection system in a developing chamber in accordance with some embodiments of the present disclosure.

FIG. 5B illustrates a schematic top view of a jig and sensors included in a position detection system of a developing chamber in accordance with some embodiments of the present disclosure.

FIGS. 5C and 5D illustrate cross-sectional views of a position detection system obtained from the reference cross-sections A1-A1′ and B1-B1′ in FIG. 5A in accordance with some embodiments of the present disclosure.

FIGS. 6B and 6C illustrate cross-sectional views of a position detection system obtained from the reference cross-sections A1-A1′ and B1-B1′ in FIG. 6A in accordance with some embodiments of the present disclosure.

FIGS. 7B and 7C illustrate cross-sectional views of a position detection system obtained from the reference cross-sections C1-C1′ and D1-D1′ in FIG. 7A in accordance with some embodiments of the present disclosure.

FIGS. 8B and 8C illustrate cross-sectional views of a position detection system obtained from the reference cross-sections C1-C1′ and D1-D1′ in FIG. 8A in accordance with some embodiments of the present disclosure.

FIGS. 9A-9H are graphs of voltage signals generated by a position detection system against time in different working stages in accordance with some embodiments of the present disclosure.

FIG. 9I is a diagram plotting measured reflection intensity on a light barrier of a position detection system versus time with a distance sensor in accordance with some embodiments of the present disclosure.

FIG. 10 is a flowchart of a method of using a position detection system to detect positions of the rinse arm in a developing chamber with reference to FIGS. 5A-8C in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In a semiconductor developing system, the developing chamber including a rinse arm, equipped with rinse nozzles, that can move vertically and rotationally to reach specific positions for optimal wafer rinsing. However, the movement of the rinse arm may involve mechanical collisions, which can cause displacement and loosen components, leading to instability during rinsing. This can disrupt the uniform distribution of rinse solution on the wafer, potentially leaving residues that affect subsequent semiconductor processing steps.

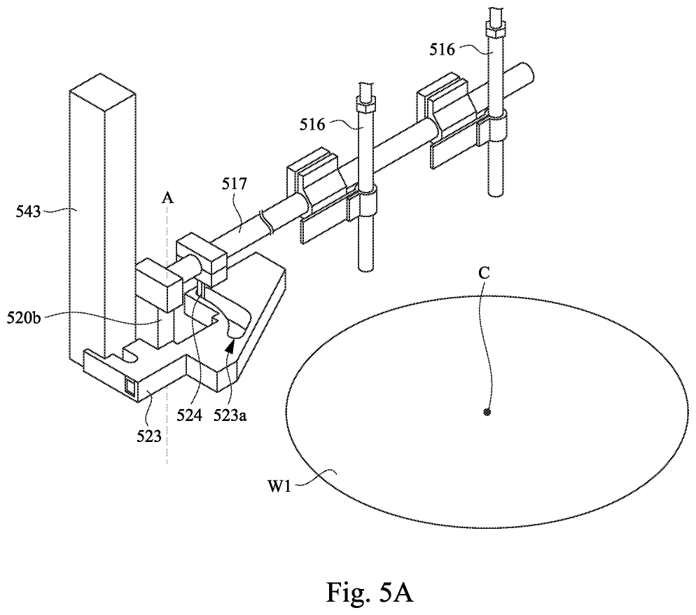

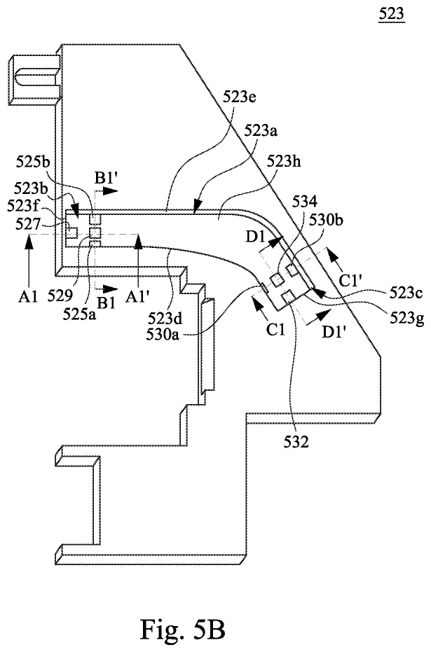

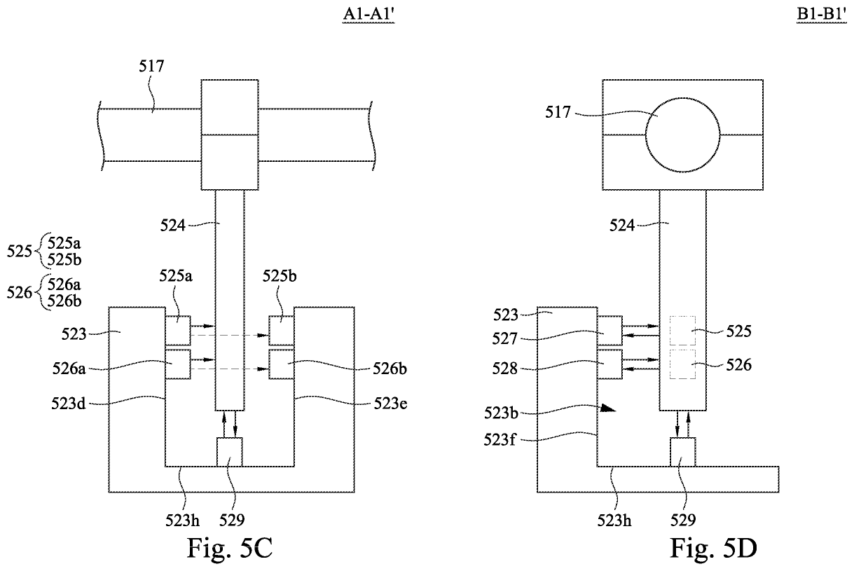

Therefore, the present disclosure provides a position detection system for the developing chamber. The position detection system is designed to monitor the position of the rinse arm during various operational stages (as shown in FIGS. 5A-8C) and verify that it aligns with predefined positions. This ensures the rinse nozzles mounted on the rinse arm can be optimally positioned to properly clean the wafer. In some embodiments, should the position detection system identify any deviation from the expected state of the rinse arm, it promptly sends an abnormality alert to the developing chamber. Upon receiving this alert, operations within the developing chamber can be halted in a timely manner, allowing for a comprehensive inspection and maintenance of the internal components of the developing chamber.

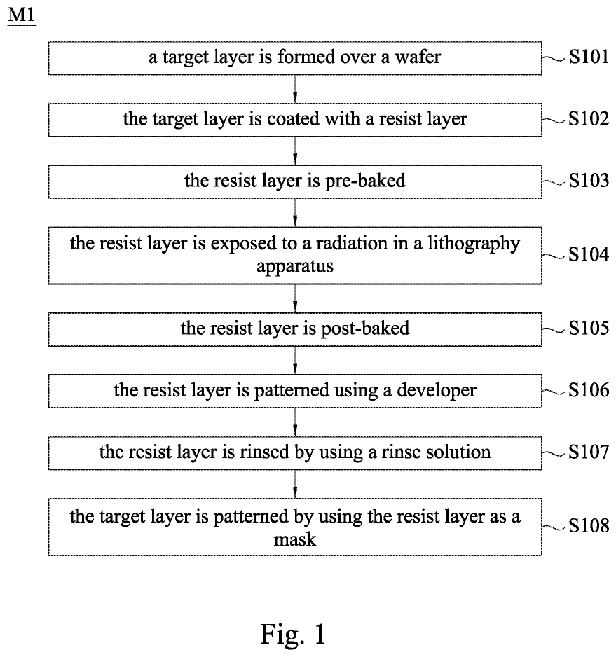

Reference is made to FIG. 1. FIG. 1 illustrates an exemplary method M1 for semiconductor manufacturing in accordance with some embodiments of the present disclosure. The method M1 includes a relevant part of the entire manufacturing process. The method M1 may be implemented, in whole or in part, by a system employing deep ultraviolet (DUV) lithography, extreme ultraviolet (EUV) lithography, electron beam (e-beam) lithography, x-ray lithography, and other appropriate lithography processes to improve pattern dimension accuracy. Additional operations can be provided before, during, and after the method M1, and some operations described can be replaced, eliminated, modified, moved around, or relocated for additional embodiments of the method. One of ordinary skill in the art may recognize other examples of semiconductor fabrication processes that may benefit from aspects of the present disclosure. The method M1 is an example, and is not intended to limit the present disclosure beyond what is explicitly recited in the claims.

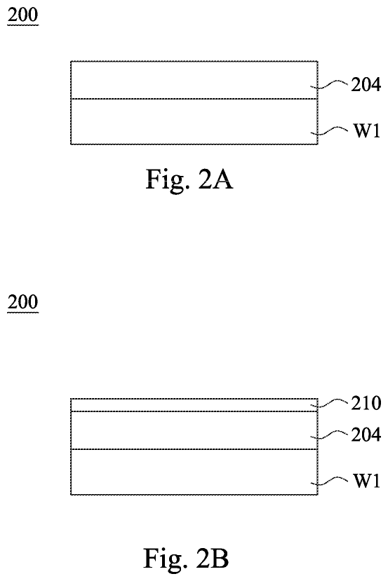

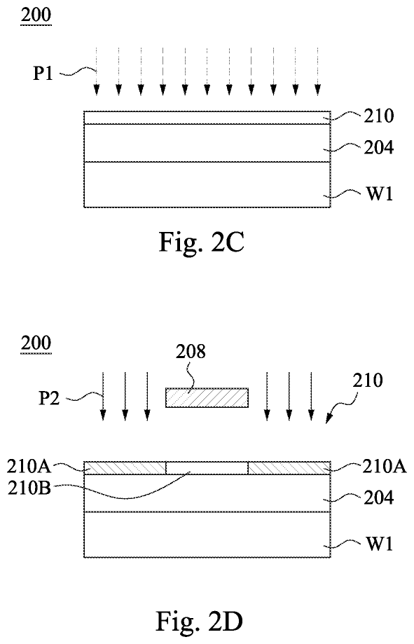

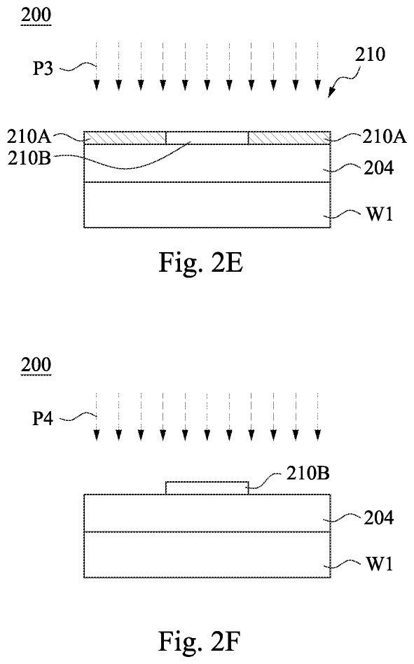

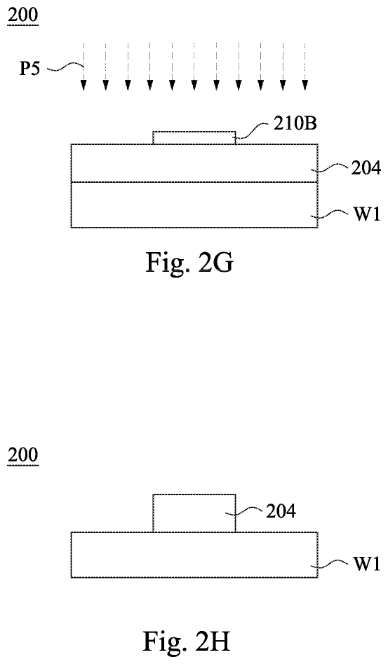

The method M1 is described below in conjunction with FIGS. 2A-2H in which a semiconductor structure 200 is fabricated by using the method M1. FIGS. 2A-2H illustrate the semiconductor structure 200 at various stages of the method M1 according to some embodiments of the present disclosure. The method M1 begins at block S101 where a target layer is formed over a wafer. Referring to FIG. 2A, in some embodiments of block S101, the wafer W1 may have a diameter about 200 mm. In some embodiments, the wafer W1 may have a diameter less than about 300 mm. In some embodiments, the wafer W1 may include one or more layers of material or composition. In some embodiments, the wafer W1 is a semiconductor substrate. In another embodiment, the wafer W1 includes silicon in a crystalline structure. In some embodiments, the wafer W1 includes other elementary semiconductors such as germanium; a compound semiconductor such as silicon carbide, gallium arsenide, indium arsenide, and indium phosphide; an alloy semiconductor such as GaAsP, AlInAs, AlGaAs, InGaAs, GaInP, and/or GaInAsP; or combinations thereof. The wafer W1 may include a silicon on insulator (SOI) substrate, be strained/stressed for performance enhancement, include epitaxial regions, include isolation regions, include doped regions, include one or more semiconductor devices or portions thereof, include conductive and/or non-conductive layers, and/or include other suitable features and layers. In some embodiments, the wafer W1 can be interchangeably referred to as a semiconductor substrate.

Alternatively or additionally, the wafer W1 may include other elementary semiconductor materials such as germanium (Ge). In some embodiments, the wafer W1 is made of a compound semiconductor such as silicon carbide (SiC), gallium arsenic (GaAs), indium arsenide (InAs), or indium phosphide (InP). In some embodiments, the wafer W1 is made of an alloy semiconductor such as silicon germanium (SiGe), silicon germanium carbide (SiGeC), gallium arsenic phosphide (GaAsP), or gallium indium phosphide (GaInP). In some embodiments, the wafer W1 includes an epitaxial layer. For example, the wafer W1 has an epitaxial layer overlying a bulk semiconductor. In some embodiments, the wafer W1 may be a germanium-on-insulator (GOI) substrate. In some embodiments, the wafer W1 may have various device elements. Examples of device elements that are formed in the wafer W1 include transistors (e.g., metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field-effect transistors (PFETs/NFETs), etc.), diodes, and/or other applicable elements. Various processes are performed to form the device elements, such as deposition, etching, implantation, photolithography, annealing, and/or other suitable processes. A target layer 204 may be formed on the wafer W1. In some embodiments, the target layer 204 may be a hard mask layer including material(s) such as amorphous silicon (a-Si), silicon oxide, silicon nitride (SiN), titanium nitride, or other suitable material or composition. In some embodiments, the target layer 204 may include an anti-reflection coating (ARC) layer such as a nitrogen-free anti-reflection coating (NFARC) layer including material(s) such as silicon oxide, silicon oxygen carbide, or plasma enhanced chemical vapor deposited silicon oxide. In some embodiments, the target layer 204 may be formed using, for example, CVD, PVD, ALD, spin-on-glass (SOG) or other suitable techniques.

Returning to FIG. 1, the method M1 then proceeds to block S102 where the target layer is coated with a resist layer. In some embodiments of block S102, as illustrated in FIG. 2B, a resist layer 210 may be coated on the target layer 204 using a spin-on coating method through a coating apparatus (not shown). In detail, a liquid film, such as a liquid material of the resist layer 210, can be dispensed on the wafer W1 through a dispensing nozzle in a processing chamber (e.g. coater) of the coating apparatus, and a wafer stage in the process chamber simultaneously rotates the wafer W1 at a rotational speed. In some embodiments, the dispensing nozzle scans across the surface of the wafer W1 during the coating. In some embodiments, the resist layer 210 may be a deep UV photoresist. The resist layer 210 may be either a positive tone or a negative tone material, which is then exposed and developed in an aqueous base solution to form a pattern which will be transferred to the underlying target layer for defining a trench thereon in subsequent processes. It is noted that the number of layer in the resist layer 210 is exemplary. In some embodiments, the resist layer 210 may be a multi-layered structure.

Returning to FIG. 1, the method M1 then proceeds to block S103 where the resist layer is pre-baked. In some embodiments of block S103, as illustrated in FIG. 2C, the wafer W1 may be transferred from the spin coater to the bake plates within the coating apparatus (not shown) to perform a pre-baking process P1 through the transferring module 33 in the coating apparatus. The pre-baking process P1 may be performed at an elevated temperature to evaporate the solvent in the resist layer 210 for a time duration sufficient to cure and dry the resist layer 210.

Returning to FIG. 1, the method M1 then proceeds to block S104 where the resist layer is exposed to a radiation in a lithography system. In some embodiments of block S104, as illustrated in FIG. 2D, an exposing process P2 is performed on the resist layer 210 in a lithography system. In some embodiments, the radiation generated by the exposing process P2 may be an I-line (365 nm), a DUV radiation such as KrF excimer laser (248 nm) or ArF excimer laser (193 nm), a EUV radiation (e.g., 13.8 nm), an e-beam, an x-ray, an ion beam, or other suitable radiations. The exposure may be performed in air, in a liquid (immersion lithography), or in a vacuum (e.g., for EUV lithography and e-beam lithography). In some embodiments, the radiation generated by the exposing process P2 may be patterned with a photomask or reticle (not shown), such as a transmissive mask or a reflective mask, which may include resolution enhancement techniques such as phase-shifting and/or optical proximity correction (OPC). In some embodiments, the radiation generated by the exposing process P2 may be directly modulated with a predefined pattern, such as an IC layout, without using a photomask (maskless lithography). In some embodiments, the radiation generated by the exposing process P2 may irradiate portions 210A of the resist layer 210 according to a pattern 208, either with a mask or maskless. Specifically, the irradiated portions 210A of the resist layer 210 may be portions exposed by the pattern 208. In some embodiments, the resist layer 210 may be a positive resist and the irradiated portions 210A become soluble in a developing chemical. In some embodiments, the resist layer 210 may be a negative resist and the unexposed portions 210B become insoluble in a developing chemical.

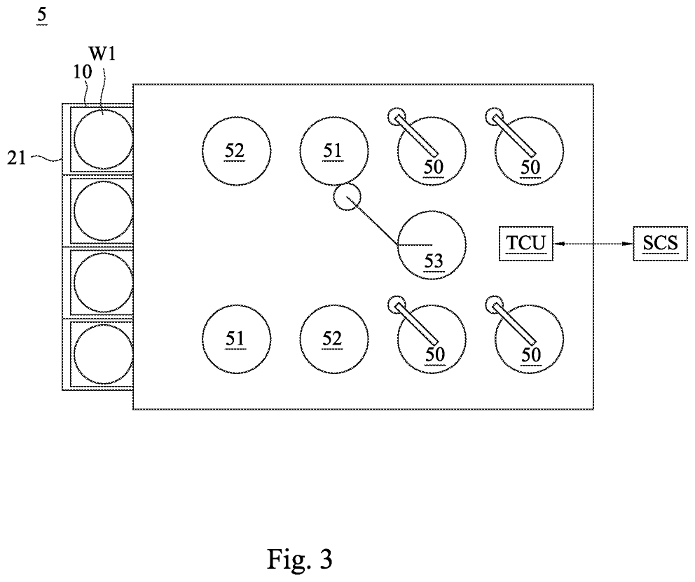

Returning to FIG. 1, the method M1 then proceeds to block S105 where the resist layer is post-baked. In some embodiments of block S105, as illustrated in FIG. 2E, a post-baking process P3 is performed on the resist layer 210 through a bake plate 52 in a developing apparatus (see FIG. 3). In some embodiments, the post-bake process P3 may be used in order to assist in the generating, dispersing, and reacting of the acid/base/free radical generated from the impingement of the energy upon the photoactive compounds in the resist layer 210 during the exposure in the radiation generated by the exposing process P2 (see FIG. 2D). Such assistance can help to create or enhance chemical reactions which generate chemical differences and different polarities between the irradiated portions 210A and the unexposed portions 210B within the resist layer 210. These chemical differences results in differences in the solubility between the irradiated portions 210A and the unexposed portions 210B.

In some embodiments, the cross-sectional view of the wafer W1 in FIG. 2E will be described along with the drawing shown in FIG. 3. Some of the described stages can be replaced or eliminated in different embodiments. As shown in FIG. 3, after the exposing process P2 is complete, a wafer carrier 10 docked on a load port of the exposure apparatus (not shown) retrieves the wafer W1 and then is transferred to the developing apparatus 5. Subsequently, the wafer carrier 10 is docked on the load port 21 of the developing apparatus 5, and then the wafer W1 in the wafer carrier 10 is transferred to the bake plate 52 to perform the post-baking process P3 thereon. As shown in FIG. 3, the developing apparatus 5 may include processing chambers that include developing chamber 50 to develop the exposed resist layer 210 (see FIG. 2F), chill plates 51, and bake plates 52. The developing apparatus 5 may further include input/output load ports 21 and transferring module 53. The transferring module 53 can pick up wafer W1 from the input/output load ports 21, moves them between the different processing chambers and delivers then to a loading bay of the developing apparatus 5. In some embodiments, the transferring module 53 can be interchangeably referred to as a substrate handler or a robot. These devices, which are often collectively referred to as the track, are under the control of a track control unit TCU which is itself controlled by the supervisory control system SCS.

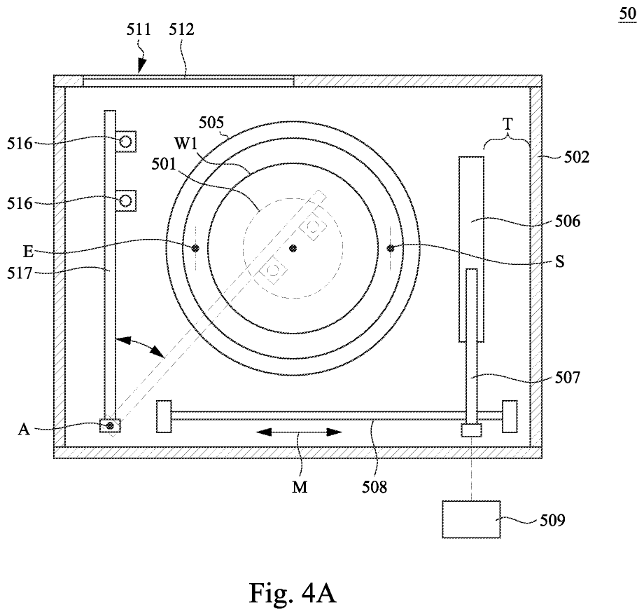

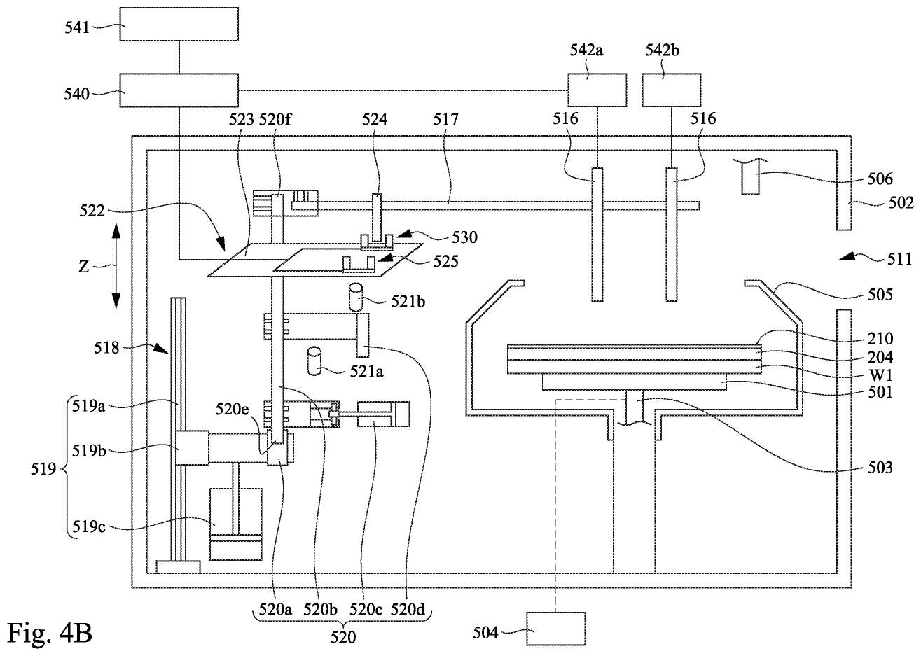

Returning to FIG. 1, the method M1 then proceeds to block S106 where the resist layer is patterned using a developing chamber. In some embodiments of block S106, as illustrated in FIG. 2F, a developing process P4 is performed to the exposed resist layer 210 on the wafer W1 by a developing solution supply nozzle 506 (see FIG. 4A) of the developing chamber 50 in the developing apparatus 5. The developing process P4 introduces a developing chemical to the irradiated portions 210A shown in FIG. 2E. Subsequently, the irradiated portions 210A can be removed by the developing chemical and results in portions 210B. In some embodiments, the developing chemical may be dissolved in a solvent. In one example, the developing chemical may be a positive tone developing chamber, e.g., containing tetramethylammonium hydroxide (TMAH) dissolved in an aqueous solution. In some embodiments, the developing chemical may be a negative tone developing chamber, e.g., containing n-Butyl Acetate (nBA) dissolved in an organic solvent. In some embodiments, the developing chemical can be interchangeably referred to as a developer.

In some embodiments, the cross-sectional view of the wafer W1 in FIG. 2F will be described along with the drawings shown in FIGS. 4A and 4B. Some of the described stages can be replaced or eliminated in different embodiments. FIGS. 4A and 4B illustrate schematic top view and cross-sectional view of a developing chamber in a developing apparatus in accordance with some embodiments of the present disclosure. After the post-baking process P3 on the wafer W1 is complete, the wafer W1 is transferred from the bake plates 52 to the chill plate 51, and then is further transferred from the chill plate 51 to the developing chamber 50 to perform the developing process P4 on the wafer W1.

The structure of the developing chamber 50 will be explained in detail. As shown in FIGS. 4A and 4B, a spin chuck 501 which is a suction-holder for sucking and holding the wafer W1 is provided in a casing 502 of the developing chamber 50. In some embodiments, the spin chuck 501 can be interchangeably referred to as a wafer chuck. The casing 502 is provided with a carrier opening 511 through which the wafer W1 is carried in/out and a shutter 512 for opening/closing the carrier opening 511. Except when the wafer W1 is carried in/out, the shutter 512 is closed to prevent a treatment solution from being scattered from within the casing 502 and maintain a predetermined atmosphere therein. A rotary drive mechanism 503 having, for example, a motor or the like, for rotating the spin chuck 501 is provided under the spin chuck 501. The operation of the rotary drive mechanism 503 is rotatably controlled by a rotation controller 504, and the rotary drive mechanism 503 is structured to be able to rotate the wafer W1 for a predetermined rotation time and at a predetermined rotation speed and rotation acceleration or to stop the wafer W1. An annular cup 505 with its upper face open is provided outside the outer periphery of the spin chuck 501 to surround the outer periphery of the spin chuck 501 so as to catch the developing solution and the like scattered from the wafer W1 which is suction-held on the spin chuck 501 and rotated, thereby preventing the units therearound from being contaminated.

Inside the casing 502, as shown in FIGS. 4A and 4B, the developing solution supply nozzle 506 as a developing solution supply nozzle for supplying the developing solution to the wafer W1, and rinse nozzles 516 for supplying the rinse solution to the upper face of the wafer W1 are provided. The rinse solution can be provided from rinse solution sources 542a and 542b. The developing solution supply nozzle 506, as shown in FIG. 4A, is held in such a manner to be hung from an arm 507. The arm 507 is structured to be freely movable on a rail 508 which extends in one direction (a direction shown by the arrow M in FIG. 4A) in the casing 502, and its moving speed and moving timing are controlled by a movement controller 509. The structure allows the developing solution supply nozzle 506 to move above and parallel to the wafer W1 along the direction M. The arm 507 has a structure including a motor and the like so as to move in the vertical direction to optimally adjust the distance between the tip of a discharge port of the developing solution supply nozzle 506 and the wafer W1 when the developing solution is supplied. In some embodiments, the arm 507 can be interchangeably referred to as a lateral arm.

The wafer W1 can be carried into the developing chamber 50 by the transferring module 53 and suction-held on the spin chuck 501. The developing solution is supplied to the entire surface of the wafer W1, resulting in the formation of a developing solution film with a predetermined thickness. In some embodiment, the developing solution supply nozzle 506 which has been waiting at the waiting position T can move to a start position S (shown in FIG. 4A) which is inside the annular cup 505 and outside one end of the wafer W. At the start position S, the developing solution supply nozzle 506 starts to discharge the developing solution, and continues trial discharge until its discharge condition becomes stable. Subsequently, the developing solution supply nozzle 506 can move from the start position S outside the one end of the wafer W to an end position E outside the other end thereof at a speed of 60 mm/s to 200 mm/s while discharging the developing solution, whereby the step of supplying the developing solution is performed. Simultaneously with the supply of the developing solution onto the wafer W1 by the developing solution supply nozzle 506, the wafer W1 starts to be developed, and developing is performed while the wafer W1 remains stationary for a predetermined period of time. After the developing in stationary condition is completed, the rotation of the wafer W1 as a stirring step for eliminating concentration difference which occurs due to time difference in the supply of the developing solution onto the wafer W1 is started. At this time, the wafer W1 is rotated for a predetermined rotation time at a predetermined rotation speed under the control of the rotation controller 504. When the rotation is started, the developing solution on the wafer W1 is cast off and stirred, whereby the concentration of the developing solution within the surface of the wafer W1 is made uniform.

Returning to FIG. 1, the method M1 then proceeds to block S107 where the resist layer is rinsed by using a rinse solution. In some embodiments of block S107, as illustrated in FIG. 2G, a rinse process P5 is performed to dispense a rinse solution onto the wafer W1 by the rinse nozzle 516. In some embodiments, the rinse solution can be any proper solvent to effectively wash away the irradiated portions 210A (see FIG. 2E) of the resist layer 210, which is reacted with the developing chemical. In some embodiments, the rinse solution may be deionized water. In some embodiments, there are a plurality of rinse nozzle 516 (e.g., 2-10) disposed on the rinse arm 517. The rinse process P5 can be in-situ performed with the developing process P4. In some embodiments, the rinse process P5 may be ex-situ performed with the developing process P4. In some embodiments, the cross-sectional view of the wafer W1 in FIG. 2G will be described along with the drawing shown in FIGS. 4A-8C. Some of the described stages can be replaced or eliminated in different embodiments. FIGS. 5A-8C illustrate schematic views of various stages of a method for operating a positioning module with a position detection system in a developing chamber in accordance with some embodiments of the present disclosure.

As shown in FIGS. 4A and 4B. The rinse nozzle 516 which discharges the rinse solution, for example, pure water is supported by a rinse arm 517. This rinse arm 517 is structured to be rotatably movable by a drive mechanism 518. The rinse nozzle 516 is located to be able to supply the rinse solution to the center of the wafer W1, for example, when the rinse arm 517 is positioned above the center of the wafer W1. Thus, the rinse solution supplied onto the wafer W1 which is being rotated is spread over the entire surface of the wafer W1 to thereby uniformly wash the entire surface of the wafer W1. When the supply of the rinse solution is stopped, the wafer W1 is rotated at a higher speed and dried. After the completion of this step of drying the wafer W1, the developing treatment of the wafer W1 is completed, and the wafer W1 is carried out of the developing chamber 50 by the transferring module 53. In some embodiments, the rinse arm 517 can be interchangeably referred to as a lateral arm.

In some embodiments, the drive mechanism 518 may include a plurality of moving assemblies including a lifter 519 and a rotor 520. The lifter 519 is configured to control a vertical movement of the drive mechanism 518, and may include a vertical slide rail 519a, a carrier 519b movably mounted on the vertical slide rail 519a, and an actuator 519c. In some embodiments, the lifter 519 can be interchangeably referred to as an up/down cylinder. The rotor 520 is configured to control a rotation movement of the drive mechanism 518, and may include a theta axis that includes base 520a, a rotating shaft 520b, an actuator 520c, and a stopper 520d. In some embodiments, the rotor 520 can be interchangeably referred to as an in/out cylinder. The lifter 519 and the rotor 520 can be independently controlled respectively, and can be activated in a moderate acceleration and deceleration during the movement thereof to prevent a position shift of the rinse nozzle 516 on the rinse arm 517.

The vertical slide rail 519a of the lifter 519 can be connected to the casing 502 of the developing chamber 50 by suitable connection means. The vertical slide rail 519a of the lifter 519 may be connected to the rotor 520 through the carrier 519b, and the rinse nozzle 516 and the rinse arm 517 can be mounted on the rotor 520. Thereby, the vertical slide rail 519a can guide the rinse arm 517 and the rinse nozzle 516 mounted on the rinse arm 517 in the Z direction through the carrier 519b actuated by the actuator 519c, such that the drive mechanism 518 can move the rinse nozzle 516 among different heights in the developing chamber 50. An end 520e of the rotating shaft 520b of the rotor 520 can be connected to the carrier 519b of the lifter 519 through the base 520a, and a bearing (not shown) can be disposed between the rotating shaft 520b and the base 520a. Another end 520f of the rotating shaft 520b of the rotor 520 can be connected to the rinse arm 517. Thereby, the rotor 520 can rotate the rinse arm 517 and the rinse nozzle 516 in the Z direction through the rotating shaft 520b actuated by the actuator 520c, such that the drive mechanism 518 can rotate the rinse nozzle 516 among different angle in the developing chamber 50.

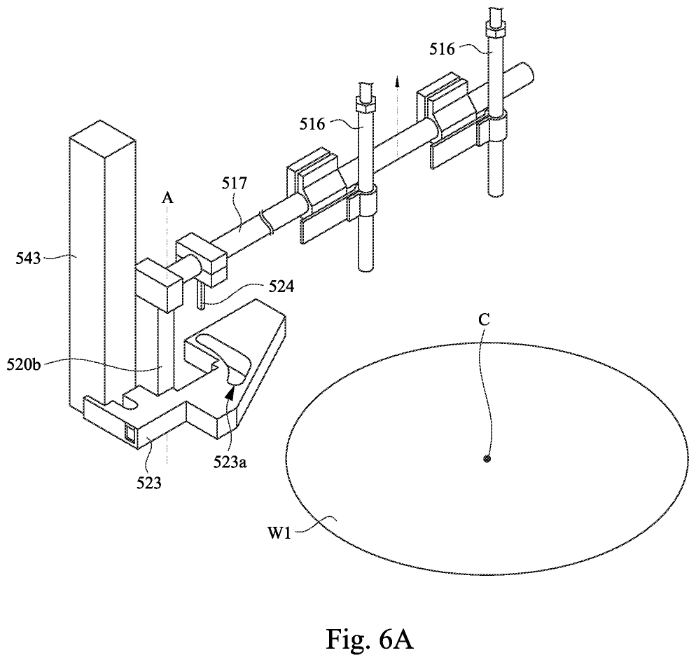

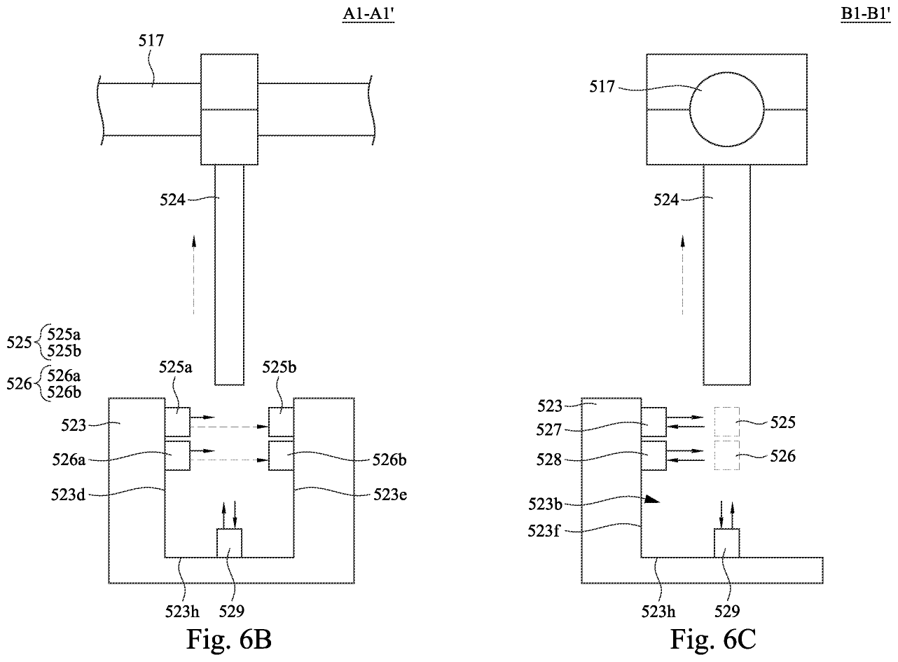

In the initial configuration, the rinse arm 517 (and the rinse nozzles 516) is situated at a first altitude (or height) defined as the home position, which is characteristically non-overlapping with either the spin chuck 501 or the wafer W1 (see FIGS. 5A, 5C, and 5D). In some embodiments, the home position can be interchangeably referred to as a home point. Following this setup, a vertical repositioning of the rinse arm 517 is executed by employing the lifter 519 of the drive mechanism 518. This results in an elevation of the rinse arm 517 to a second altitude (or height) higher than the first height (see FIGS. 6A-6C).

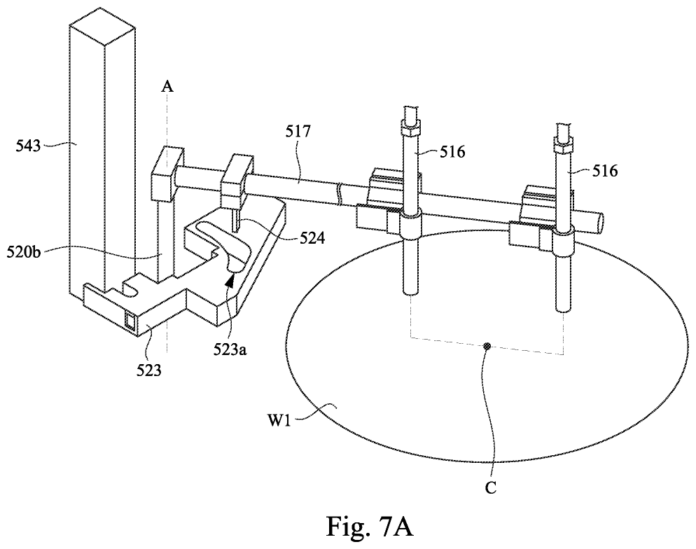

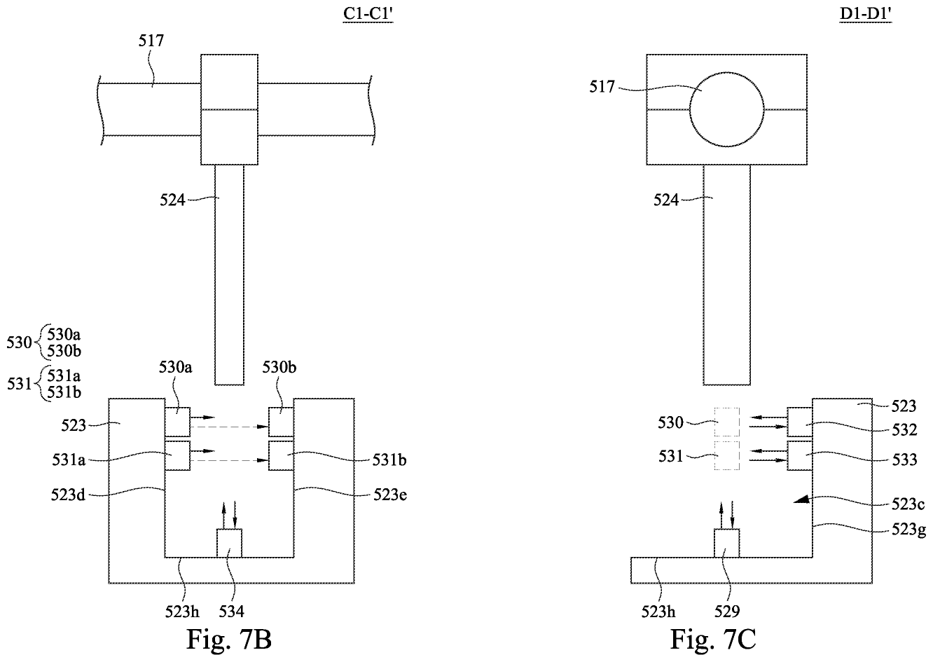

Subsequently, the rinse arm 517 can rotate to a central position at this second height (see FIGS. 7A-7C). This rotation is facilitated by the rotor 520 of the drive mechanism 518. The default (standard) setting for this central position is such that the rinse arm 517 can end up located over the wafer W1, and the center C of the wafer W1 can be aligned with the center of the projections of the rinse nozzles 516 mounted on the rinse arm 517. In some embodiments, the center position can be interchangeably referred to as a center point. In this configuration, the rinse arm 517 (and the rinse nozzles 516) overlaps with either the spin chuck 501 or the wafer W1. The journey of the rinse arm 517 from the home position to the center position is controlled mechanically. Specifically, the rotation is impeded by the stopper 520d, installed on the rotating shaft 520 of the rotor 520. Additionally, stop pillars 521a and 521b are mounted in the developing chamber 50, corresponding to the home and center positions. As the rinse arm 517 swivels from the home position towards the center position, it collides with the stop pillar 521b at the center position with the stopper 520d, ceasing further rotation and ensuring a halt at the center position.

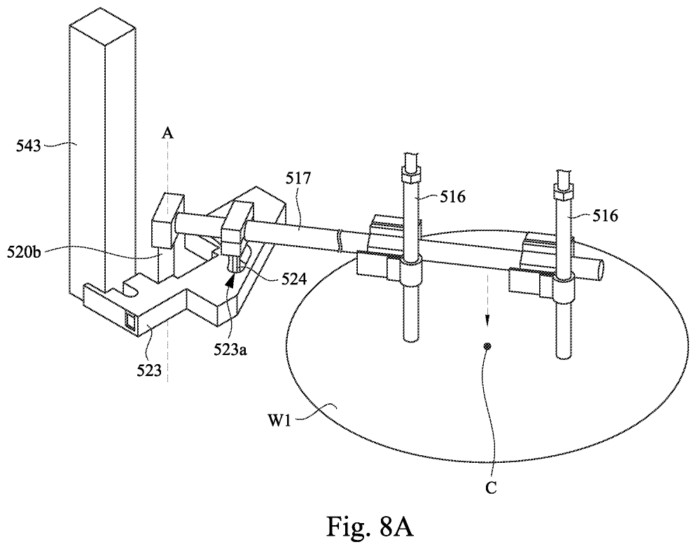

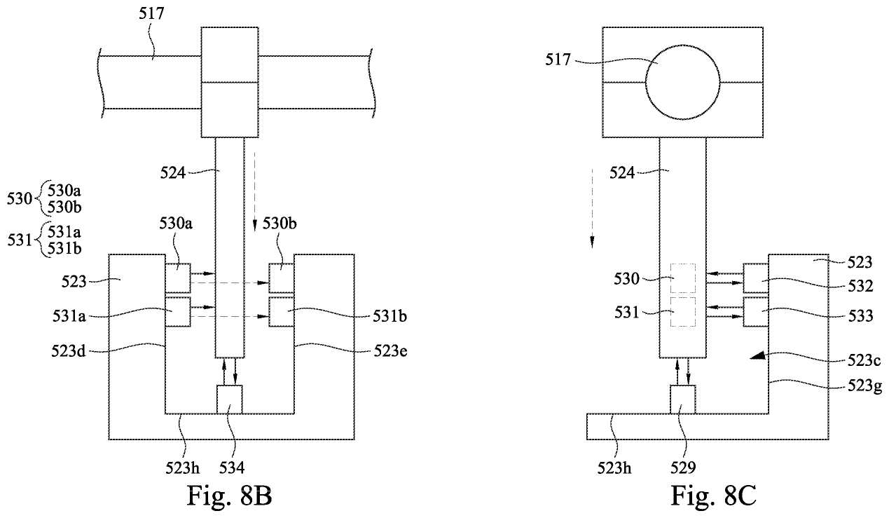

Subsequently, the rinse arm 517 is lowered to a third altitude (or height) (see FIGS. 8A-8C), which is lower than the second altitude, utilizing the lifter 519 of the drive mechanism 518. Subsequently, rinse nozzles 516 release the rinse solution to dispense onto the wafer W1, thereby accomplishing the rinse process. In some embodiment, the third altitude can be substantially the same as the first altitude. In some embodiment, the third altitude can be greater than the first altitude. In some embodiment, the third altitude can be less than the first altitude.

In light of the preceding sequence of rotational motion and mechanical collision, the rinse arm 517 may experience positional displacement (or shift). Consequently, the rinse nozzles 516, which are affixed onto the rinse arm 517, are subjected to a similar positional displacement (or shift). The collision may also lead to loosening of the components, specifically the rinse arm 517 and the rinse nozzles 516. As these parts become less tightly affixed, their stability during the rinse process P5 is compromised, introducing a shakiness or vibration in the rinse nozzles 516 during the rinse process P5. This displacement and shaking disrupt the positioning of the rinse nozzles 516, thereby the thoroughness of the rinse process on the wafer W1. The improper or non-uniform distribution of the rinse solution across the wafer W1 due to the displacement of the rinse nozzles 516 can lead to residues remaining on the wafer. This situation can adversely affect the manufacturing process of semiconductor structures. That is, impurities or residues that remain on the wafer W1 post-rinse can cause defects in the subsequent steps of semiconductor processing.

Therefore, the present disclosure provides a position detection system 522 (see FIG. 4B). The position detection system 522 is designed to monitor the position of the rinse arm 517 during various operational stages (as shown in FIGS. 5A-8C) and verify that it aligns with predefined positions. This ensures the rinse nozzles 516 mounted on the rinse arm 517 are optimally positioned to properly clean the wafer W1. Should the position detection system 522 identify any deviation from the expected state of the rinse arm 517, it promptly sends an abnormality alert to the developing chamber 50. Upon receiving this alert, operations within the developing chamber 50 can be halted in a timely manner, allowing for a comprehensive inspection and maintenance of the internal components of the developing chamber 50. In some embodiments, the position of the rinse arm 517 can be automatically corrected using a calibration device.

The position detection system 522 may include multiple sensors 525-534 (see FIGS. 5B-5D, 6B, 6C, 7B, 7C, 8B, and 8C), a jig 523 laterally enclosing the rotating shaft 520b of the rotor 520 (or a vertical axis) (see FIG. 4B), a trench 523a (see FIG. 5B) situating in the jig 523 and housing the sensors 525-534, and a light-blocking element 524 mounted on the rinse arm 517 and operating in coordination with the sensors 525-534 to detect positional deviations of the rinse arm 517 and the rinse nozzle 516. In the home position (see FIGS. 5A and 6A), the light-blocking element 524 on the rinse arm 517 is located in two different positions. As depicted in FIG. 5A, the light-blocking element 524 extends downward into the first end 523b of the trench 523a, while in FIG. 6A, the light-blocking element 524 is positioned above the first end 523b, relative to its position in FIG. 5A. At the end 523b of the trench 523a, the sensors 525-529 monitor the light-blocking element 524 to identify any positional deviation of the rinse arm 517 and the rinse nozzle 516. When the rinse arm 517 is in the center position (FIGS. 7A and 8A), the light-blocking element 524 is located in two different positions. As shown in FIG. 7A, the light-blocking element 524 is positioned above the second end 523c of the trench 523a, while in FIG. 8A, the light-blocking element 524 extends downward into the trench 523a relative to its position in FIG. 7A. At the end 523c of the trench 523a, the sensors 530-534 monitor the light-blocking element 524 to identify any positional deviation of the rinse arm 517 and the rinse nozzle 516. In some embodiments, the sensors 525-529 can be interchangeably referred to as home sensors, and the sensors 530-534 can be interchangeably referred to as center sensors. In some embodiments, the jig 523 can be fixed the developing chamber 50 through a column 543 (see FIG. 5A). In some embodiments, the trench 523a can be interchangeably referred to as an arc trench or a rounding trench.

By way of example and not limitation, the sensors 525, 526, 530, and 531 (FIGS. 4B and 5B) can be thrubeam sensors (or through-beams, or transmitted-beam sensors) and function through the arrangement of two separate components: transmitters 525a, 526a, 530a, and 531a mounted on a sidewall 523d of the trench 523a, and receivers 525b, 526b, 530b, and 531b mounted on a sidewall 523e of the trench 523a opposite to the sidewall 523d. The transmitters 525a, 526a, 530a, and 531a each emits optical beam, often infrared, which is aimed directly at the receivers 525b, 526b, 530b, and 531b located on the opposite side. Detection is accomplished when a target (e.g., the light-blocking element 524) intercepts the direct line of sight between the transmitters 525a, 526a, 530a, and 531a and the receivers 525b, 526b, 530b, and 531b. The interruption of the optical axis signals the presence of the light-blocking element 524.

The receivers 525b, 526b, 530b, and 531b (FIGS. 4B and 5B) of the sensors 525, 526, 530, and 531 can be responsible for transducing the incoming optical signal into a corresponding electrical signal. This electrical signal is subsequently transmitted to the control unit 540, enabling it to ascertain the presence of the light-blocking element 524.

As illustrated in FIGS. 5A, 5C, 5D, and 8A-8C, when the light-blocking element 524 is in its default position, it is positioned within the trench 523a and aligned with the light signal's path, which is being transmitted and received by the sensor 525, 526, 530, or 531. The presence of the light-blocking element 524 in this path obstructs the light signal, preventing its receipt by the sensor's receiver 525b, 526b, 530b, or 531b. Consequently, the receiver's output voltage, in this scenario, is high. In reference to the states presented in FIGS. 5A, 5C, 5D, and 8A-8C, the control unit 540 can discern the position of the light-blocking element 524, such as the home position or center position at the first altitude, by detecting the high voltage output. It can thus confirm that the rinse arm 517 and the rinse nozzle 516 are at the pre-determined position.

On the contrary, in FIGS. 6A-6C and 7A-7C, when the light-blocking element 524 is in its default position, it is positioned externally to the trench 523a and does not impede the path of the light signal transmitted and received by the sensor 525, 526, 530, or 531. As such, the light-blocking element 524 doesn't interfere with the light signal, permitting its receipt by the receiver 525b, 526b, 530b, or 531b. Consequently, the receiver's output voltage, in this scenario, is low. In reference to the states presented in FIGS. 6A-6C and 7A-7C, the control unit 540 can discern that the light-blocking element 524 is not at the home position or center position at the first altitude, by detecting the low voltage output. Therefore, this voltage differentiation can act as an effective monitoring and control mechanism for the system.

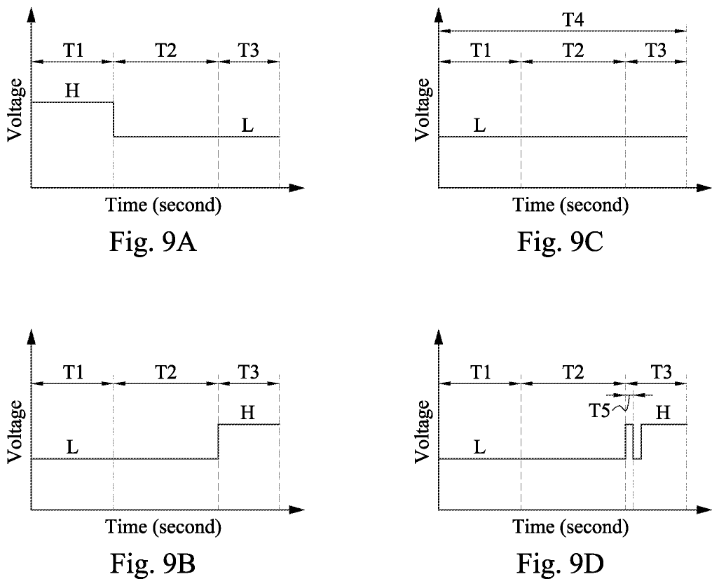

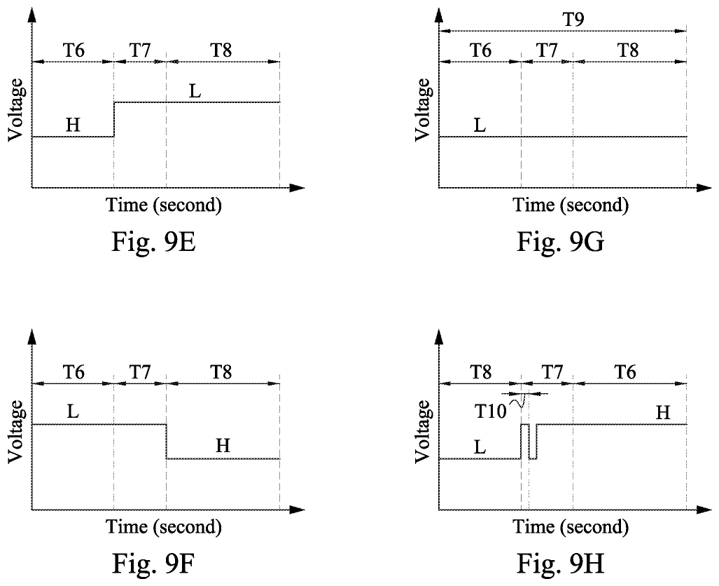

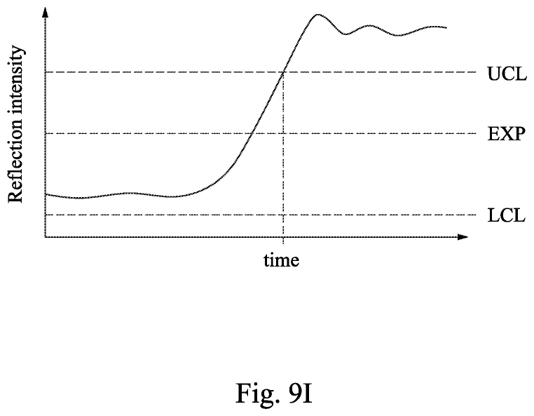

Referring to FIGS. 9A-9D, FIGS. 9A and 9B illustrate the rinse arm 517 under default setting. FIG. 9A illustrates the variation in the electrical signal emitted or generated by the sensor 525 or 526 as the rinse arm 517 moves from the home position to the center position. FIG. 9B illustrates the variation in electrical signal emitted or generated by the sensor 530 or 531 as the rinse arm 517 moves from the home position to the center position. FIGS. 9C and 9D illustrate abnormal scenarios pertaining to the rinse arm 517. These abnormal scenarios represent electrical signal variations from the sensor 530 or 531 under situations where the rinse arm 517 deviates from its expected behavior or position.

In FIGS. 9A-9D, specific time durations denote distinct states of the rinse arm 517. Specifically, the time duration T1 corresponds to the status of the rinse arm 517 as illustrated in FIGS. 5A, 5C, and 5D. The time duration T2 corresponds to the state of the rinse arm 517 as illustrated in FIGS. 6A-6C and 7A-7C. The time duration T3 corresponds to the state of the rinse arm 517 as illustrated in FIGS. 8A-8C. These time durations T1, T2, and T3, thus, capture the sequential stages of the rinse arm 517 during its movement from the home position to the center position, while the corresponding electrical signals emitted from the sensors sensor 525, 526, 530, or 531 provide a time-based analysis of the positional variations of the rinse arm.

When the rinse arm 517 reaches the center position, it halts due to a mechanical collision. This collision has the potential to cause the loosening of the constituent components related to the rinse arm 517. In FIG. 9C, the sensor 530 and/or 531 would ordinarily detect the presence of the light-blocking element 524 and subsequently output a high voltage. However, because the light-blocking element 524 has not arrived at its designated position due to the loosening of components, the sensor 530 and/or 531 outputs a low voltage instead. The maintenance of this low voltage over an extended period (e.g. time duration T4), which is longer than usual, indicates an abnormal positioning of the rinse arm 517. In some embodiments, the time duration T4 may be greater than about 4 seconds, such as about 4, 5, 6, 7, 8, 9, or 10 seconds. Additionally, in FIG. 9D, the loosening of the constituent components related to the rinse arm 517 could lead to the rinse arm 517 exhibiting a shaking motion upon reaching the center position. This irregular movement can cause fluctuations in the sensor's voltage output, leading to a brief spike. The abrupt spike, marked by a short time duration T5 of low voltage, is indicative of an abnormality in the positioning of the rinse arm 517. This abnormal position could potentially disrupt the process flow.

In the case of time duration T4, an extended time duration of low voltage is indicative of an abnormal positioning of the rinse arm 517. The rinse arm 517 may not arrive at its designated position in a longer time duration due to a mechanical loosening. That is, if the rinse arm 517 is rotating slower than its expected speed, this could potentially cause it to reach its destination later than expected. On the other hand, time duration T5 relates to a brief spike in the sensor's voltage output due to the rinse arm 517 exhibiting a shaking motion upon reaching the center position. This abrupt spike in the sensor's output could also be indicative of an irregular rotation speed. If the rinse arm 517 is shaking or oscillating rapidly, this could be due to it rotating faster than its expected speed, causing the rinse arm 517 to overshoot its position and then quickly correct its position, leading to the shaking motion. The short time duration T5 of low voltage could thus indicate a faster rotation speed. By monitoring these time durations and comparing them against expected values, the system can effectively detect any abnormal rotation speed of the rinse arm 517. This allows the system to not only detect issues with positioning but also with speed, providing a more comprehensive monitoring system for the position of the rinse arm 517.

As shown in FIGS. 5C, 5D, 6B, and 6C, the sensors 525 and 526 can be positioned to vertically overlap with each other at the home position. As shown in FIGS. 7B, 7C, 8B, and 8C, the sensors 530 and 531 can be positioned to vertically overlap with each other at the center position. Establishing two sets of sensors at the same position, positioned to overlap vertically, provides an enhancement to the system's ability to monitor the position and movement of the rinse arm 517 with greater precision. This arrangement enables the detection of tilt or deviation from the required position in rinse arm 517. If the rinse arm 517 strays from its intended level orientation, the vertically overlapping sensors can capture this discrepancy. This misalignment is indicated when one of the overlapping sensors identifies the presence of the light-blocking element 524, and another one of the overlapping sensors does not identify the presence of the light-blocking element 524. This differential in detection signals the existence of a tilt in the rinse arm 517 that may affect the efficiency and precision of the rinse process. In addition, this arrangement can allow for an evaluation of a vertical position (e.g., drop height) of the rinse arm 517. For example, if the rinse arm 517 doesn't lower to the desired height, the upper sensor can still detect this inadequacy. The lower sensor may fail to register the light-blocking element 524, but the upper sensor will continue to detect it. This variation in the sensors' outputs illustrates that the rinse arm 517 hasn't reached its specified position. Therefore, this arrangement can contribute to a more accurate and reliable control of the rinse arm 517's position, improving the quality and efficiency of the wafer rinse process. It also can aid in early fault detection, thereby reducing potential downtime and associated costs of rectification.

By way of example and not limitation, the sensors 527, 528, 529, 532, 533, and 534 (see FIG. 5B) can be diffuse-reflective sensors (or diffused sensors), each employ a unified design containing both a corresponding transmitter and a corresponding receiver within a single housing. This type of sensor functions by emitting a light beam, usually infrared, towards the target (e.g., light-blocking element 524). When the emitted beam strikes the light-blocking element 524, it is scattered in various directions. A portion of this scattered or diffused light is reflected back to the sensor where it is received and detected. The sensors 527 and 528 mounted on a sidewall 523f of the trench 523a at the first end 523b, the sensors 532 and 533 mounted on a sidewall 523g of the trench 523a at the second end 523c, the sensor 529 mounted on a bottom surface 523h of the trench 523a at the first end 523b, and the sensor 534 mounted on the bottom surface 523h of the trench 523a at the second end 523c. The placement of these sensors can allow for precise and comprehensive coverage in tracking the position of the light-blocking element 524.

In order to make an accurate determination of the position of the light-blocking element 524 based on the detected reflection intensity, a range of acceptable values can be established. This range is calculated based on a standard deviation from an expected value. As illustrated in FIG. 9I, an upper control limit (UCL) is determined by adding one standard deviation of the comparison result to the expected reflection intensity (EXP). Similarly, a lower control limit (LCL) is set by subtracting one standard deviation of the comparison result from the expected reflection intensity (EXP). The difference between the UCL and LCL at a specific time gives us the range of acceptable values. The sensors 527, 528, 529, 532, 533, and 534 can be used to determine whether the light-blocking element 524 is at the home position or center position by comparing the detected reflection intensity with the pre-determined acceptable range. If the detected reflection intensity falls within the acceptable range, it suggests that the light-blocking element 524 is positioned at either the home or center position. Conversely, a detected reflection intensity that falls outside of the UCL and LCL boundaries suggests that the light-blocking element 524 may not be at its predetermined position, signifying a potential anomaly in the positioning.

As illustrated in FIGS. 5A, 5C, 5D, and 8A-8C, when the light-blocking element 524 is in its default position, it is positioned within the trench 523a and aligned with the light signal's path, which is being transmitted and received by the sensor 527, 528, 532, or 533. The presence of light blocking element 524 in this path reflects a portion of the light signal, thereby helping it to be received by sensors 527, 528, 532, and 533. Consequently, in this case, the reflection intensity will be between the upper control limit and the lower control limit. In reference to the states presented in FIGS. 5A, 5C, 5D, and 8A-8C, the control unit 540 can discern the position of the light-blocking element 524, such as the home position or center position at the first altitude, by detecting the reflection intensity. It can thus confirm that the rinse arm 517 and the rinse nozzle 516 are at the pre-determined position.

On the contrary, in FIGS. 6A-6C and 7A-7C, when the light-blocking element 524 is in its default position, it is positioned externally to the trench 523a and does not reflect the light signal transmitted by the sensor 527, 528, 532, or 533. In reference to the states presented in FIGS. 6A-6C and 7A-7C, the control unit 540 can discern that the light-blocking element 524 is not at the home position or center position at the first altitude, by detecting the reflection intensity. Therefore, this voltage differentiation can act as an effective monitoring and control mechanism for the system.

As shown in FIGS. 5D and 6C, the sensors 527 and 528 can be positioned to vertically overlap with each other at the home position. As shown in FIGS. 7C and 8C, the sensors 532 and 533 can be positioned to vertically overlap with each other at the center position. Establishing two sets of sensors at the same position, positioned to overlap vertically, provides an enhancement to the system's ability to monitor the position and movement of the rinse arm 517 with greater precision. This arrangement enables the detection of tilt or deviation from the required position in rinse arm 517. If the rinse arm 517 strays from its intended level orientation, the vertically overlapping sensors can capture this discrepancy. This misalignment is indicated when one of the overlapping sensors identifies the presence of the light-blocking element 524 earlier than another one of the overlapping sensors. This differential in detection signals the existence of a tilt in the rinse arm 517 that may affect the efficiency and precision of the rinse process. In addition, this arrangement can allow for an evaluation of a vertical position (e.g., drop height) of the rinse arm 517. For example, if the rinse arm 517 doesn't lower to the desired height, the upper sensor can still detect this inadequacy. The lower sensor may fail to register the light-blocking element 524, but the upper sensor will continue to detect it. This variation in the sensors' outputs illustrates that the rinse arm 517 hasn't reached its specified position. Therefore, this arrangement can contribute to a more accurate and reliable control of the rinse arm 517's position, improving the quality and efficiency of the wafer rinse process. It also can aid in early fault detection, thereby reducing potential downtime and associated costs of rectification.

In some embodiments, the sensor 529 (see FIGS. 5C, 5D, 6B, and 6C) and the sensor 534 (see FIGS. 7B, 7C, 8B, and 8C) can be installed to monitor the vertical movement of the rinse arm 517. As diffuse-reflective sensors, they emit a light signal and receive its reflected portion from the light-blocking element 524. The intensity of the received reflection offers information about the relative position of the rinse arm 517. Specifically, when the rinse arm 517 is at the appropriate height, the reflected light from the rinse arm 517 will fall within a predetermined intensity range. This is considered as the normal operation, and the rinse arm 517 is confirmed to be at the optimal elevation. However, if the rinse arm 517 is too high or too low, the reflection intensity will deviate from this predefined acceptable range. For example, if the light-blocking element 524 is too high, it will be farther from the sensor 529 or 534, causing the reflected light intensity detected by the sensors to decrease. Conversely, if the rinse arm is too low, it will be closer to the sensor 529 or 534, and the reflected light intensity detected by the sensors will increase.

When the control unit 540 (see FIG. 4B) identifies a potential anomaly with rinse arm 517 based on the sensor feedback, it takes immediate action to ensure the integrity of the manufacturing process to the wafer W1 and the developing chamber 50. The control unit 540 including a microcontroller unit (MCU) control board generates an alarm signal that is transmitted to the developing chamber 50 and/or an alarm system 541 (see FIG. 4B). This alarm signal acts as an immediate instruction to halt all operations of the machinery within the developing chamber 50. This is a safety measure designed to prevent any damage to the wafer W1 or the developing chamber 50, avoiding further complications or malfunctions. Once the operation is halted, an inspection related to the rinse arm 517 can be performed. This inspection ensures that the status and functionality of the rinse arm 517 are evaluated, determining whether there is a misalignment that needs to be addressed. In some embodiments, the control unit 540 may have the capacity to rectify the detected anomalies autonomously. Upon recognizing an abnormality, the control unit 540 can manipulate the drive mechanism 518 to adjust the position of the rinse arm 517 automatically. This process ensures the rinse arm 517 is restored to its correct operational position. Subsequently, the sensors proceed with a subsequent evaluation of the rinse arm's location. This secondary detection verifies whether the corrective action was successful and the rinse arm 517 is correctly positioned. If the sensors confirm the rinse arm's proper alignment, normal operations in the developing chamber 50 can resume. In some embodiments, the control unit 540 can be electrically connected to the rinse solution sources 542a and 542b and controls the providing of the rinse solution via the rinse nozzles 516. For example, if the abnormal scenarios of the rinse arm 517 are detected, the control unit 540 can transmit the signal to the rinse solution sources 542a and 542b to halt the providing of the rinse solution.

Referring to FIGS. 9E-9H, FIGS. 9E and 9F illustrate the rinse arm 517 under default setting. FIG. 9E illustrates the variation in the electrical signal emitted or generated by the sensor 525 or 526 as the rinse arm 517 moves from the center position to the home position. FIG. 9F illustrates the variation in electrical signal emitted or generated by the sensor 530 or 531 as the rinse arm 517 moves from the center position to the home position. FIGS. 9G and 9H illustrate abnormal scenarios pertaining to the rinse arm 517. These abnormal scenarios represent electrical signal variations from the sensor 526 or 527 under situations where the rinse arm 517 deviates from its expected behavior or position.

In FIGS. 9E-9H, specific time durations denote distinct states of the rinse arm 517. Specifically, the time duration T6 corresponds to the status of the rinse arm 517 as illustrated in FIGS. 8A-8C. The time duration T7 corresponds to the state of the rinse arm 517 as illustrated in FIGS. 6A-6C and 7A-7C. The time duration T8 corresponds to the state of the rinse arm 517 as illustrated in FIGS. 5A, 5C, and 5D. These time durations T6, T7, and T8, thus, capture the sequential stages of the rinse arm 517 during its movement from the center position to the home position, while the corresponding electrical signals emitted from the sensors sensor 525, 526, 530, or 531 provide a time-based analysis of the positional variations of the rinse arm.

When the rinse arm 517 reaches the home position, it halts due to a mechanical collision. This collision has the potential to cause the loosening of the constituent components related to the rinse arm 517. In FIG. 9G, the sensor 525 and/or 526 would ordinarily detect the presence of the light-blocking element 524 and subsequently output a high voltage. However, because the light-blocking element 524 has not arrived at its designated position due to the loosening of components, the sensor 525 and/or 526 outputs a low voltage instead. The maintenance of this low voltage over an extended period (e.g. time duration T9), which is longer than usual, indicates an abnormal positioning of the rinse arm 517. Additionally, in FIG. 9H, the loosening of the constituent components related to the rinse arm 517 could lead to the rinse arm 517 exhibiting a shaking motion upon reaching the home position. This irregular movement can cause fluctuations in the sensor's voltage output, leading to a brief spike. The abrupt spike, marked by a short time duration T10 of low voltage, is indicative of an abnormality in the positioning of the rinse arm 517. This abnormal position could potentially disrupt the process flow.

In the case of time duration T9, an extended time duration of low voltage is indicative of an abnormal positioning of the rinse arm 517. The rinse arm 517 may not arrive at its designated position in a longer time duration due to a mechanical loosening. That is, if the rinse arm 517 is rotating slower than its expected speed, this could potentially cause it to reach its destination later than expected. On the other hand, time duration T10 relates to a brief spike in the sensor's voltage output due to the rinse arm 517 exhibiting a shaking motion upon reaching the center position. This abrupt spike in the sensor's output could also be indicative of an irregular rotation speed. If the rinse arm 517 is shaking or oscillating rapidly, this could be due to it rotating faster than its expected speed, causing the rinse arm 517 to overshoot its position and then quickly correct its position, leading to the shaking motion. The short time duration T10 of low voltage could thus indicate a faster rotation speed. By monitoring these time durations and comparing them against expected values, the system can effectively detect any abnormal rotation speed of the rinse arm 517. This allows the system to not only detect issues with positioning but also with speed, providing a more comprehensive monitoring system for the position of the rinse arm 517.

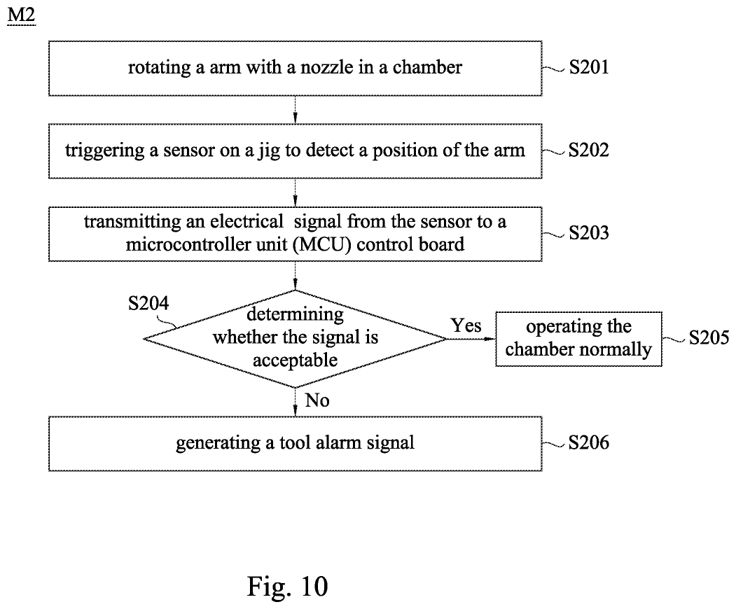

FIG. 10 is a flowchart of a method M2 of using a position detection system to detect positions of the rinse arm in a developing chamber with reference to FIGS. 5A-8C in accordance with some embodiments of the present disclosure. The method M2 includes a relevant part of the entire drying process. It is understood that additional operations may be provided before, during, and after the operations shown by FIG. 10, and some of the operations described below can be replaced or eliminated for additional embodiments of the method. The order of the operations/processes may be interchangeable.

The method M2 begins at block S201. In some embodiments of block S201 with reference to FIGS. 5A-8C, the rinse arm 517 equipped with the rinse nozzles 516a begins its rotational movement from the designated home point towards the center point within the developing chamber 50. In some embodiments, this rotation could be automated and governed by a pre-set sequence or triggered by specific conditions within the developing chamber 50.

The method M2 begins at block S202. In some embodiments of block S202 with reference to FIGS. 5A-8C, sensors (e.g., sensors 525-534) mounted on the jig 523 are activated to meticulously track (or detect) the positions of the rinse arm 517 during its movement in real time. These sensors monitor its progress, capturing data about the positions of the rinse arm 517.

The method M2 begins at block S203. In some embodiments of block S203 with reference to FIGS. 5A-8C, the sensors (e.g., sensors 525-534) transmit an electrical signal to the control unit 540 including the microcontroller unit control board. This transmission carries information of the rinse arm 517. The electrical signal may include various data including voltage levels, each indicative of specific positional characteristics of the rinse arm 517.

The method M2 begins at block S204. In some embodiments of block S204 with reference to FIGS. 5A-8C, the control unit 540 determines whether the electrical signal is acceptable based on predefined criteria. These criteria could be specific voltage ranges correlating to the proper positioning of the rinse arm 517. If the signal falls within an acceptable range, the process moves forward to block S205. However, if the signal indicates a deviation or irregularity, the process moves forward to block S206.

The method M2 begins at block S205. In some embodiments of block S205 with reference to FIGS. 5A-8C, in this case, the electrical signal falls within the acceptable range, the process proceeds with regular operation of the developing chamber 50. This means the rinse arm 517 is correctly positioned, and the system can continue its normal functioning.

The method M2 begins at block S206. In some embodiments of block S206 with reference to FIGS. 5A-8C, in this case, the electrical signal does not fall within the acceptable range, it suggests a possible irregularity in the positioning of the rinse arm 517. The control unit 540 can generate a tool alarm signal. This tool alarm signal can serve as a notification system, alerting relevant operators or systems about the issue. This facilitates can enable timely corrective measures to ensure efficient functioning of the overall system.

Returning to FIG. 1, the method M1 then proceeds to block S108 where the target layer is patterned by using the resist layer as a mask. In some embodiments of block S108, as illustrated in FIG. 2H, the target layer 204 can be patterned by using the patterned resist 210B as an etch mask, thereby transferring the pattern of the patterned resist 210B to the target layer 204. For example, the target layer 204 may be etched using a dry (plasma) etching, a wet etching, and/or other etching methods. In some embodiments, the patterned resist 210B may be partially or completely consumed during the etching of the target layer 204. In some embodiments, any remaining portion of the patterned resist 210B may be stripped off, leaving the target layer 204 over the wafer W1. The method M1 may proceed to forming a final pattern or an IC device on the target layer 204. In some embodiments, the wafer W1 may be a semiconductor substrate and the method M1 can proceed to form planar devices, such as planar FETs, fin field-effect transistors (FinFETs), or nano-FETs.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a position detection system for the developing chamber. The position detection system is designed to monitor the position of the rinse arm during various operational stages and verify that it aligns with predefined positions. This ensures the rinse nozzles mounted on the rinse arm can be optimally positioned to properly clean the wafer. In some embodiments, should the position detection system identify any deviation from the expected state of the rinse arm, it promptly sends an abnormality alert to the developing chamber. Upon receiving this alert, operations within the developing chamber can be halted in a timely manner, allowing for a comprehensive inspection and maintenance of the internal components of the developing chamber.

In some embodiments, a method includes placing a semiconductor substrate in a developing chamber; rotating a rinse arm, with a rinse nozzle, in the developing chamber based on a vertical axis; detecting a positioning status of the rinse arm through a position detection system; determining whether the positioning status of the rinse arm is acceptable through the position detection system; in response to the determination determines that the positioning status of the rinse arm is acceptable, performing a rinse process on the semiconductor substrate through the rinse nozzle installed on the rinse arm. In some embodiments, the method further includes in response to the determination determines that the positioning status of the rinse arm is not acceptable, issuing an alarm signal through the position detection system. In some embodiments, the position detection system includes a jig, a first sensor, and a light-blocking element. The jig is positioned below the rinse arm and around the vertical axis. The jig has a trench therein, and the trench is around the vertical axis. The first sensor installed on a sidewall of the trench. The light-blocking element is mounted on the rinse arm, and downwardly extends from the rinse arm towards the trench of the jig. When the rinse arm is in motion, the light-blocking element overlaps the trench of the jig from a top view. In some embodiments, the step of rotating is performed by rotating the rinse arm from a first position to a second position, and from the top view, the first position is located outside the semiconductor substrate, and the second position is located over the semiconductor substrate, and the first sensor is configured to detect the positioning status of the rinse arm in the first position through the light-blocking element. In some embodiments, the method further includes: in response to the determination determines that the positioning status of the rinse arm is not acceptable when the first sensor not detect the rinse arm, through the light-blocking element in a time duration. In some embodiments, the position detection system includes a second sensor installed on the sidewall of the trench, and the second sensor is configured to detect the positioning status of the rinse arm in the second position through the light-blocking element. In some embodiments, the method further includes: in response to the determination determines that the positioning status of the rinse arm is not acceptable when the first and second sensors do not detect the rinse arm, through the light-blocking element, at the same time continuously for more than a time duration. In some embodiments, the step of detecting the positioning status of the rinse arm is performed in real time. In some embodiments, the method further includes detecting a rotational speed of the rinse arm through the position detection system. In some embodiments, the method further includes determining whether the rotational speed of the rinse arm is acceptable through the position detection system.

In some embodiments, a method includes moving a lateral arm, with a nozzle, in a developing chamber from a first position to a second position around a wafer chuck in the developing chamber, wherein from a top view, the nozzle does not overlap the wafer chuck in the first position, and the nozzle overlaps the wafer chuck in the second position; detecting the lateral arm from the first and second positions through a position detection system; determining whether the lateral arm has a position shift at the first position or the second position through the position detection system; issuing a warning when the lateral arm has the position shift. In some embodiments, the step of moving the lateral arm comprises rotating the lateral arm in the developing chamber based on a vertical axis from the first position to the second position. In some embodiments, the position detection system includes a jig, a first light transmitter, a first light receiver, and a light-blocking element. The jig is positioned below the lateral arm, and the jig has a rounding trench therein. The first light transmitter is installed on a first sidewall of the rounding trench and around the first position. The first light receiver is installed on a second sidewall of the rounding trench opposite to the first sidewall and around the first position. The first light receiver is corresponding to the first light transmitter. The light-blocking element is mounted on the lateral arm, and downwardly extends from the lateral arm toward the rounding trench. In some embodiments, when the lateral arm is in the first position, the light-blocking element of the position detection system has a lower portion in the rounding trench and laterally between the first light transmitter and the first light receiver. In some embodiments, the position detection system further includes a second light transmitter and a second light receiver. The second light transmitter is installed on the first sidewall of the rounding trench and around the second position. The second light receiver is installed on the second sidewall of the rounding trench and around the second position. The second light receiver is corresponding to the second light transmitter.

In some embodiments, an apparatus includes a developing chamber, a wafer chuck, a rinse arm, a rinse nozzle, a jig, a light-blocking element, and a first sensor. The wafer chuck is in the developing chamber. The rinse arm is adjacent to the wafer chuck. The rinse arm can being rotatable about a vertical axis. The rinse nozzle is mounted on the rinse arm. The jig is disposed below the rinse arm and around the vertical axis. The jig has a trench thereon, and the trench is around the vertical axis. The light-blocking element is mounted on the rinse arm. The light-blocking element downwardly extends from the rinse arm towards the trench of the jig. When the rinse arm is in a rotational motion, the light-blocking element is configured to extend into the trench. The first sensor is mounted on a sidewall of the trench in the jig. The first sensor is located at a first side of the trench. The first sensor is configured to detect the light-blocking element. In some embodiments, the apparatus further includes a second sensor mounted on the sidewall of the trench in the jig. The second sensor is located at a second side of the trench opposite to the first side. The second sensor is configured to detect the light-blocking element. In some embodiments, the apparatus further includes a control unit electrically connected to the first sensor. The control unit is configured to determine whether a positioning status of the rinse arm is acceptable. In some embodiments, the apparatus further includes a second sensor mounted on the sidewall of the trench in the jig. The second sensor is vertically aligned with the first sensor. In some embodiments, the apparatus further includes a second sensor mounted on a bottom of the trench in the jig.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
placing a semiconductor substrate in a developing chamber;
rotating a rinse arm, with a rinse nozzle, in the developing chamber based on a vertical axis;
detecting a positioning status of the rinse arm through a position detection system;
determining whether the positioning status of the rinse arm is acceptable through the position detection system; and
in response to the determination determines that the positioning status of the rinse arm is acceptable, performing a rinse process on the semiconductor substrate through the rinse nozzle installed on the rinse arm.

2. The method of claim 1, further comprising:
in response to the determination determines that the positioning status of the rinse arm is not acceptable, issuing an alarm signal through the position detection system.

3. The method of claim 1, wherein the position detection system comprises:
a jig positioned below the rinse arm and around the vertical axis, the jig having a trench therein, the trench being around the vertical axis;
a first sensor installed on a sidewall of the trench; and
a light-blocking element mounted on the rinse arm, the light-blocking element downwardly extending from the rinse arm towards the trench of the jig,
wherein when the rinse arm is in motion, the light-blocking element overlaps the trench of the jig from a top view.

4. The method of claim 3, wherein the step of rotating is performed by rotating the rinse arm from a first position to a second position, and from the top view, the first position is located outside the semiconductor substrate, and the second position is located over the semiconductor substrate, and the first sensor is configured to detect the positioning status of the rinse arm in the first position through the light-blocking element.

5. The method of claim 4, further comprising:
in response to the determination determines that the positioning status of the rinse arm is not acceptable when the first sensor does not detect the rinse arm, through the light-blocking element in a time duration.

6. The method of claim 4, wherein the position detection system comprises:
a second sensor installed on the sidewall of the trench, and the second sensor is configured to detect the positioning status of the rinse arm in the second position through the light-blocking element.

7. The method of claim 6, further comprising:
in response to the determination determines that the positioning status of the rinse arm is not acceptable when the first and second sensors do not detect the rinse arm, through the light-blocking element, at the same time continuously for more than a time duration.

8. The method of claim 1, wherein the step of detecting the positioning status of the rinse arm is performed in real time.

9. The method of claim 1, further comprising:
detecting a rotational speed of the rinse arm through the position detection system.

10. The method of claim 9, further comprising:
determining whether the rotational speed of the rinse arm is acceptable through the position detection system.

11. A method, comprising:
moving a lateral arm, with a nozzle, in a developing chamber from a first position to a second position around a wafer chuck in the developing chamber, wherein from a top view, the nozzle does not overlap the wafer chuck in the first position, and the nozzle overlaps the wafer chuck in the second position;
detecting the lateral arm from the first and second positions through a position detection system;
determining whether the lateral arm has a position shift at the first position or the second position through the position detection system; and
issuing a warning when the lateral arm has the position shift.

12. The method of claim 11, wherein the step of moving the lateral arm comprises rotating the lateral arm in the developing chamber based on a vertical axis from the first position to the second position.

13. The method of claim 11, wherein the position detection system comprises:
a jig positioned below the lateral arm, the jig having a rounding trench therein;
a first light transmitter installed on a first sidewall of the rounding trench and around the first position;
a first light receiver installed on a second sidewall of the rounding trench opposite to the first sidewall and around the first position, wherein the first light receiver is corresponding to the first light transmitter; and
a light-blocking element mounted on the lateral arm, the light-blocking element downwardly extending from the lateral arm toward the rounding trench.

14. The method of claim 13, wherein when the lateral arm is in the first position, the light-blocking element of the position detection system has a lower portion in the rounding trench and laterally between the first light transmitter and the first light receiver.

15. The method of claim 13, wherein the position detection system further comprises:
a second light transmitter installed on the first sidewall of the rounding trench and around the second position; and
a second light receiver installed on the second sidewall of the rounding trench and around the second position, wherein the second light receiver is corresponding to the second light transmitter.

16. An apparatus, comprising:
a developing chamber;
a wafer chuck in the developing chamber;
a rinse arm adjacent to the wafer chuck, the rinse arm being rotatable about a vertical axis;
a rinse nozzle mounted on the rinse arm;
a jig disposed below the rinse arm and around the vertical axis, the jig having a trench thereon, the trench being around the vertical axis;
a light-blocking element mounted on the rinse arm, the light-blocking element downwardly extending from the rinse arm towards the trench of the jig, wherein when the rinse arm is in a rotational motion, the light-blocking element extends into the trench; and
a first sensor mounted on a sidewall of the trench in the jig, the first sensor located at a first side of the trench, wherein the first sensor is configured to detect the light-blocking element.

17. The apparatus of claim 16, further comprising:
a second sensor mounted on the sidewall of the trench in the jig, the second sensor located at a second side of the trench opposite to the first side, wherein the second sensor is configured to detect the light-blocking element.

18. The apparatus of claim 16, further comprising:
a control unit electrically connected to the first sensor, wherein the control unit is configured to determine whether a positioning status of the rinse arm is acceptable.

19. The apparatus of claim 16, further comprising:
a second sensor mounted on the sidewall of the trench in the jig, wherein the second sensor is vertically aligned with the first sensor.

20. The apparatus of claim 16, further comprising:
a second sensor mounted on a bottom of the trench in the jig.
